(19) United States
(12) Patent Application Publication
(10) Pub. No.: US 2008/0285437 A1
(43) Pub. Date: Nov. 20, 2008

(54) ETHERNET PROTECTION SWITCHING SYSTEM

(75) Inventor: Joe Polland, Eden Prairie, MN (US)

Correspondence Address: FOGG & POWERS LLC, 10 SOUTH FIFTH STREET, SUITE 1000, MINNEAPOLIS, MN, 55402, US

(73) Assignee: ADC DSL SYSTEMS, INC., Eden Prairie, MN (US)

(21) Appl. No.: 11/750,688

(22) Filed: May 18, 2007

(51) Int. Cl. G01R 31/08

(52) U.S. Cl. 370/219

(57) ABSTRACT

An Ethernet-protection-switch system comprising a first transceiver node having Ethernet ports and transmit/receive lines communicatively coupled to a respective one of the Ethernet ports. The Ethernet ports include one active-receive Ethernet port and at least one backup-receive Ethernet port. Each transmit/receive line carrying duplicates of a data packet sent from a communicatively coupled second transceiver node. The duplicated data packet input from a transmit/receive line to the active-receive Ethernet port is received at the first transceiver node. The duplicated data packet input from a transmit/receive line to a respective one of the at least one backup-receive Ethernet port is discarded at the first transceiver node. If the transmit/receive line inputting the duplicated data packet to the active-receive Ethernet port fails, one of the at least one backup-receive Ethernet ports begins to function as the active-receive Ethernet port. The first transceiver node is configured to output duplicated data packets from each of the Ethernet ports for transmission on each of the transmit/receive lines.

### CROSS REFERENCE TO RELATED APPLICATIONS

This application is related to U.S. patent application Ser. No. 11/462,782 having a title of “MAPPING EXTERNAL PORT USING VIRTUAL LOCAL AREA NETWORK” (the '782 application) filed on Aug. 7, 2006. The '782 application is hereby incorporated herein by reference.

### BACKGROUND

Protection switching is used in carrier class telecommunications networks, such as SONET to allow communications to be maintained through even when a link goes down or is broken. Essentially, the systems using protection switching employ redundant communication links between point A and B; a primary link and a back-up link. If the primary link goes down, this is detected and points A and B switch to the back-up link. However, the protection switching for Ethernet is not available.

### SUMMARY

In a first aspect, an Ethernet-protection-switch system comprising a first transceiver node having Ethernet ports and transmit/receive lines communicatively coupled to a respective one of the Ethernet ports. The Ethernet ports include one active-receive Ethernet port and at least one backup-receive Ethernet port. Each transmit/receive line carrying duplicates of a data packet sent from a communicatively coupled second transceiver node. The duplicated data packet input from a transmit/receive line to the active-receive Ethernet port is received at the first transceiver node. The duplicated data packet input from a transmit/receive line to a respective one of the at least one backup-receive Ethernet port is discarded at the first transceiver node. If the transmit/receive line inputting the duplicated data packet to the active-receive Ethernet port fails, one of the at least one backup-receive Ethernet ports begins to function as the active-receive Ethernet port. The first transceiver node is configured to output duplicated data packets from each of the Ethernet ports for transmission on each of the transmit/receive lines.

In a second aspect, a method to protection switch Ethernet ports comprising receiving a duplicated data packet at an active-receive Ethernet port of a protected Ethernet switch, receiving a duplicated data packet at a backup-receive Ethernet port of the protected Ethernet switch, adding a virtual local area network tag to the duplicated data packet received at the active-receive Ethernet port, assigning a virtual local area network identifier to the virtual local area network tag based on the Ethernet port that received the duplicated data packet to form a modified data packet, discarding the duplicated data packet received on the backup-receive Ethernet port, and sending the modified data packet to a network-processor port based on the virtual local area network identifier.

In a third aspect, a method to protection switch Ethernet ports comprising receiving a duplicated data packet at an active-receive Ethernet port of a protected Ethernet switch, receiving a duplicated data packet at a backup-receive Ethernet port of the protected Ethernet switch, discarding the duplicated data packet received at the backup-receive Ethernet port, and sending the duplicated data packet received at the active-receive Ethernet port to a network-processor port.

In a fourth aspect, a program product comprising program instructions embodied on a storage medium that are operable to cause a processor to add a virtual local area network tag to a duplicated data packet received at an active-receive Ethernet port, assign a virtual local area network identifier to the virtual local area network tag based on the active-receive Ethernet port that received the active data packet to form a modified data packet, discard the duplicated data packet received on a backup-receive Ethernet port, and send the modified data packet to a network-processor port of the Ethernet switch based on the virtual local area network identifier.

In a fifth aspect, a program product comprising program instructions embodied on a storage medium that are operable to cause a processor to discard a duplicated data packet received at a backup-receive Ethernet port of a protected Ethernet switch, and send a duplicated data packet received at an active-receive Ethernet port of the protected Ethernet switch to a network-processor port.

### DRAWINGS

FIGS. 1-3 show block diagrams for various embodiments of Ethernet-protection-switch systems.

FIG. 4 is a block diagram of an embodiment of a virtual local area network data packet modified for ingress to a transceiver node.

FIG. 5 is a diagram of an embodiment of internal paths for a modified data packet received as an unmodified data packet at an Ethernet port of a transceiver node.

FIG. 6 is a diagram of an embodiment of internal paths for modified data packets sent as unmodified data packets from Ethernet ports of transceiver node.

FIG. 7 is a block diagram of an embodiment of a virtual local area network data packet modified for ingress to a transceiver node.

FIG. 8 is a flow diagram of one embodiment of a method to protection switch input data packets for ingress in accordance with the present invention.

FIG. 9 is a flow diagram of one embodiment of a method to protection switch input data packets for ingress in accordance with the present invention.

FIG. 10 is a flow diagram of one embodiment of a method to protection switch input data packets for ingress in accordance with the present invention.

FIG. 11 is a flow diagram of one embodiment of a method to protection switch output data packets for egress in accordance with the present invention.

In accordance with common practice, the various described features are not drawn to scale but are drawn to emphasize features relevant to the present invention. Reference characters denote like elements throughout figures and text.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. The following detailed description is, therefore, not to be taken in a limiting sense.

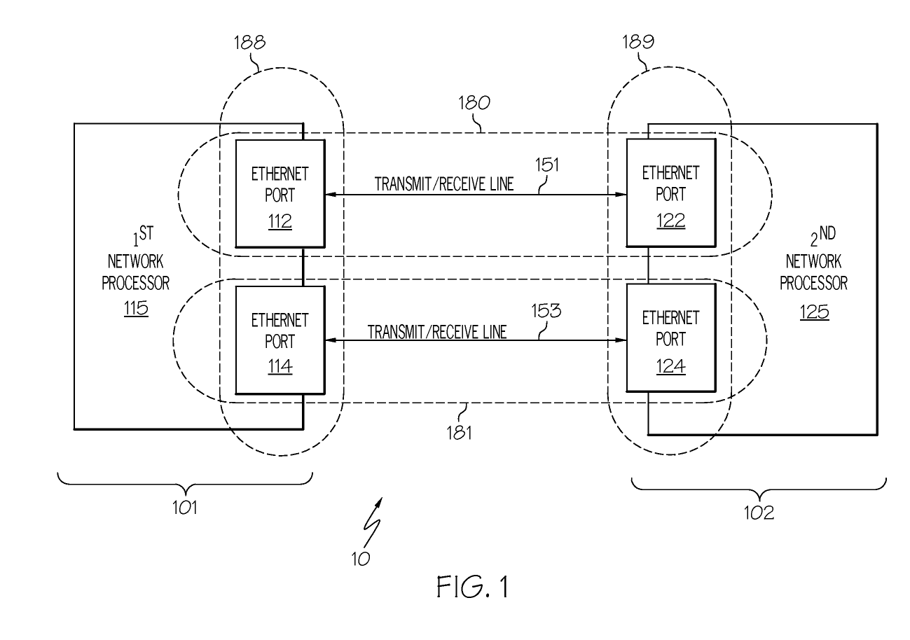

FIGS. 1-3 show block diagrams for various embodiments of Ethernet-protection-switch systems 10-12, respectively. The Ethernet-protection-switch systems provide a protection switching capability for Ethernet-based transceiver nodes. The Ethernet-protection-switch systems 10-12 include a first transceiver node including one active-receive Ethernet port and at least one backup-receive Ethernet port. One transmit/receive line is communicatively coupled to the active-receive Ethernet port. Another transmit/receive line is communicatively coupled to each of the backup-receive Ethernet ports. Each transmit/receive line carries duplicates of data packets sent from a communicatively coupled second transceiver node.

The duplicated data packet input from a transmit/receive line to the active-receive Ethernet port is received at the first transceiver node. The duplicated data packet input from a transmit/receive line to a respective one of the at least one backup-receive Ethernet port is discarded at the first transceiver node. If the transmit/receive line inputting the duplicated data packet to the active-receive Ethernet port fails, one of the backup-receive Ethernet ports begins to function as the active-receive Ethernet port. The first transceiver node is configured to output duplicated data packets from each of the Ethernet ports (both the active and backup-receive Ethernet ports) for transmission on each of the transmit/receive lines.

The Ethernet-protection-switch systems 10-12 also include a second transceiver node including one active-receive Ethernet port and at least one backup-receive Ethernet port. The transmit/receive lines are communicatively coupled to a respective one of the Ethernet ports of the second transceiver node so that the Ethernet ports in the second transceiver node are communicatively coupled to a respective one of the Ethernet ports in the first transceiver node in a point to point configuration. The protection switching described herein is implemented on full duplex point to point links. The protection switching is not implemented on half duplex and point to multipoint bus configurations.

Each transmit/receive line carries a duplicated data packet sent from the first transceiver node. The duplicated data packet input from a transmit/receive line to the active-receive Ethernet port in the second transceiver node is received at the second transceiver node, The duplicated data packet input from a transmit/receive line to a respective one of the backup-receive Ethernet ports in the second transceiver node is discarded at the second transceiver node. If the transmit/receive line inputting the duplicated data packet to the active-receive Ethernet port in the second transceiver node fails, one of the at least one backup-receive Ethernet ports in the second transceiver node begins to function as the active-receive Ethernet port. The second transceiver node is configured to output duplicated data packets from each of the Ethernet ports in the second transceiver node for transmission on each of the transmit/receive lines to the first transceiver node.

The data packets, which are transmitted and received on the transmit/receive lines that communicatively coupled the first and the second transceiver node, are duplicated on at least one transmit/receive line. As used herein the terms “data packets,” “duplicated data packets” and “duplicate data packets” are used interchangeably. A communication link includes two Ethernet ports in two respective transceiver nodes that are communicatively coupled by a transmit/receive line.

In one implementation of this embodiment, a communication link includes a backup-receive Ethernet port in the first transceiver node, the active-receive Ethernet port in the second transceiver node and the transmit/receive line communicatively coupling the two Ethernet ports. In this case, the parallel communication link comprises the backup-receive Ethernet port in the second transceiver node, the active-receive Ethernet port in the first transceiver node, and the transmit/receive line communicatively coupling these two Ethernet ports.

In another implementation of this embodiment, a communication link includes a backup-receive Ethernet port in first transceiver node, a backup-receive Ethernet port in the second transceiver node and the transmit/receive line communicatively coupling the two backup-receive Ethernet ports comprises. In this case, the parallel communication link the active-receive Ethernet port in the first transceiver node, the active-receive Ethernet port in the second transceiver node, and the transmit/receive line communicatively coupling these two active-receive Ethernet ports. The designation of a port as an active port or as a backup port is initially a user configured option.

If a failure is detected in any portion of the communication link that sends data packets to an active-receive Ethernet port, the Ethernet-protection-switch systems are protection switched. As used herein, protection switching is implemented by changing the status of the active-receive Ethernet port from “active” to “backup” while simultaneously changing the status of the backup-receive Ethernet port from “backup” to “active.” When the Ethernet-protection-switch systems are protection switched, the communication links that feeds data packets to the newly activated Ethernet port takes over the function of the primary communication link. It is to be noted that the transmit/receive line that sends data packets to the active-receive Ethernet port of one transceiver node can be within the primary communication link for that transceiver node, at the same time that another transmit/receive line that sends data packets to the active-receive Ethernet port of the other transceiver node is the primary communication link for that other transceiver node receiving communication in the opposite direction.

In one implementation of this embodiment, each transmit/receive line is two separate lines: a transmit line and a receive line. In this case the Ethernet-protection-switch systems include a transmit line for transmitting data packets from a transceiver node and a receive line for receiving data packets at the same transceiver node. The Ethernet-protection-switch systems 10-12 are each operable to protect data packets during ingress to and egress from a transceiver node with or without the use of VLAN identifiers.

FIG. 1 is a block diagram representative of the Ethernet-protection-switch system 10. The Ethernet-protection-switch system 10 includes a first network processor 115, a second network processor 125, transmit/receive line 151, and transmit/receive line 153. The first network processor 115 is also referred to herein as “network processor 115” and “transceiver node 101.” The second network processor 125 is also referred to herein as “network processor 125” and “transceiver node 102.” The transmit/receive lines 151 and 153 transmit data packets between the network processors 115 and 125. The network processor 115 includes the Ethernet port 112 and Ethernet port 114. The network processor 125 includes the Ethernet port 122 and the Ethernet port 124.

The Ethernet ports 112 and 122 communicatively coupled by a transmit/receive line 151 form a pair of Ethernet ports represented generally by the numeral 180. The Ethernet ports 114 and 124 form a pair of Ethernet ports represented generally by the numeral 181. In this manner, respective pairs 180 and 181 of Ethernet ports are communicatively coupled in a point-to-point configuration.

The Ethernet-protection-switch system 10 groups multiple Ethernet ports as a single logical port to provide protection switching as discussed in more detail below. The network processor 115 views the Ethernet ports 112 and 114 as a single logical port, so that logical port is protected by physical Ethernet ports 112 and 114. The Ethernet ports 112 and 114 form a protection-port pair 188 in the network processor 115. Likewise, the logical port of the network processor 125 is protected by physical Ethernet ports 122 and 124. The Ethernet ports 122 and 124 form a protection-port pair 189 in the network processor 125.

In one implementation of this embodiment, a configuration table in the network processor 115 defines which ports form a protection-port pair. For the network processor 115, the configuration table is shown in Table 1. The configuration table for the network processor 125 is shown in Table 2.

TABLE 1

| Logical Port | Ethernet port | Ethernet port |
|---|---|---|
| First | Ethernet port 112 | Ethernet port 114 |

TABLE 2

| Logical Port | Ethernet port | Ethernet port |
|---|---|---|
| First | Ethernet port 122 | Ethernet port 124 |

A configuration table is important when there are more than two protection-port pairs in the network processor. Table 3 shows one embodiment of a configuration table for an exemplary transceiver node or network processor that has four Ethernet ports that form two logical ports each having a protection-port pair.

TABLE 3

| Logical Port | Ethernet port | Ethernet port |
|---|---|---|
| First | First | Second |
| Second | Third | Fourth |

Table 4 shows an alternative configuration table for the exemplary transceiver node that has four Ethernet ports that form two logical ports.

TABLE 4

| Logical Port | Ethernet port | Ethernet port |
|---|---|---|
| First | First | Third |
| Second | Second | Fourth |

Duplicate data packets are transmitted on the transmit/receive line 151 and on the transmit/receive line 153 from the first network processor 115 since the network processor 115 is configured to transmit data packets from both the transmit/receive lines 151 and 153. Likewise, network processor 115 is configured to receive one of duplicated data packets from one of the transmit/receive lines 151 and 153. Only the active-receive Ethernet port receives the data packet while the backup-receive Ethernet port discards the received data packet.

In one implementation of this embodiment, the Ethernet port 112 is the protected or active-receive Ethernet port and the Ethernet port 114 is the backup-receive Ethernet port. In this case, the primary communication link for the first network processor 115 includes the active-receive Ethernet port 112, the Ethernet port 122, and the transmit/receive line 151. The backup communication link for the first network processor 115 includes the backup-receive Ethernet port 114, Ethernet port 124 and the transmit/receive line 153. In this same implementation, there are two possible scenarios for the second network processor 125. In the first scenario, the Ethernet port 124 is the protected or active-receive Ethernet port and the Ethernet port 122 is the backup-receive Ethernet port. In this case, the primary communication link for the second network processor 115 includes the active-receive Ethernet port 124, Ethernet port 114 and the transmit/receive line 153. The backup communication link for the second network processor 125 includes the backup-receive Ethernet port 122, Ethernet port 112 and the transmit/receive line 151.

In the second scenario, the Ethernet port 122 is the protected or active-receive Ethernet port and the Ethernet port 124 is the backup-receive Ethernet port. In this case, the primary communication link for the second network processor 125 includes the active-receive Ethernet port 122, Ethernet port 112, and the transmit/receive line 151. The backup communication link for the second network processor 125 includes the backup-receive Ethernet port 124, Ethernet port 114, and the transmit/receive line 153.

If any portion of the primary communication link fails for the first network processor 115, then the Ethernet port 114 becomes the active-receive Ethernet port during a protection switching process. In an exemplary case, the transmit/receive line 151 is broken. In this case, the Ethernet port 124 in the second network processor 125 must remain or become the active-receive Ethernet port since data packets sent from the Ethernet port 112 will not be received at the Ethernet port 122 over the broken transmit/receive line 151.

In another implementation of this embodiment, the Ethernet port 114 is the protected or active-receive Ethernet port and the Ethernet port 112 is the backup-receive Ethernet port. In this case, the primary communication link for the first network processor 115 includes the active-receive Ethernet port 114, Ethernet port 124 and the transmit/receive line 153. The backup communication link for network processor 125 includes the backup-receive Ethernet port 112, Ethernet port 122 and the transmit/receive line 151. Either the first or second scenario described above for the second network processor 125 is possible for this embodiment.

If any portion of the primary communication link for the first network processor 115 fails, then the transmit/receive line 151 becomes the active line and the Ethernet port 112 becomes the active-receive Ethernet port of the first network processor during a protection switching process.

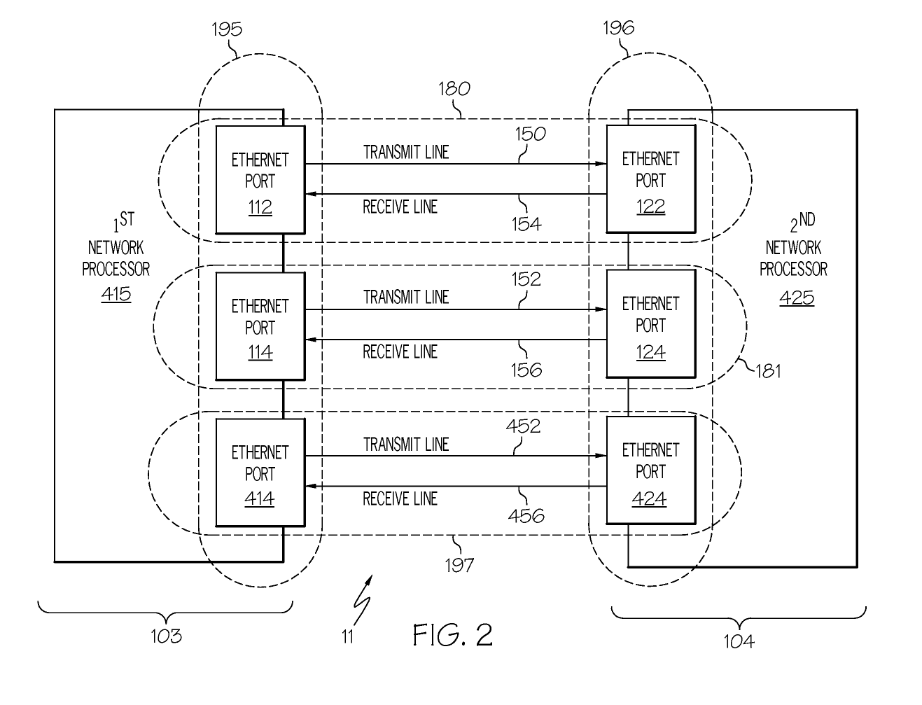

In yet another implementation of this embodiment, there are three Ethernet ports in each network processor and three pairs of Ethernet ports are communicatively coupled in a point-to-point configuration between the network processors. Such a system is shown in FIG. 2. FIG. 2 is a block diagram representative of the Ethernet-protection-switch system 11. In this embodiment the transmit/receive lines each comprise one transmit line and one receive line. The Ethernet-protection-switch system 11 includes a first network processor 415, a second network processor 425, transmit lines 150, 152 and 452 for the first network processor 415, and receive lines 154, 156 and 456 for the first network processor 415. The three Ethernet ports 112, 114 and 414 in the first network processor 415 form a protection-port triad 195. The three Ethernet ports 122, 124 and 424 in the second network processor 425 form a protection-port triad 196.

The Ethernet port 414 and the Ethernet port 424 form a pair of Ethernet ports represented generally by the numeral 197. The Ethernet port 414 and the Ethernet port 424, the transmit line 452 and the receive line 456 form a communication link.

The Ethernet-protection-switch system 11 groups multiple Ethernet ports as a single logical port to provide protection switching as discussed in more detail below. The first network processor 415 views the Ethernet ports 112, 114, and 414 of the protection-port triad 195 as a single logical port, so that logical port is protected by physical Ethernet ports 112, 114, and 414. Likewise, the second network processor 425 views the Ethernet ports 122, 124, and 424 of the protection-port triad 196 as a single logical port so that the logical port is protected by the Ethernet ports 122, 124, and 424. Table 5 shows a configuration table for such an implementation of the protection-port triad 196.

TABLE 5

| Logical Port | Ethernet port | Ethernet port | Ethernet port |
|---|---|---|---|
| First | Ethernet port | Ethernet port | Ethernet port |
| | 122 | 124 | 424 |

As shown in FIG. 2, the transmit/receive line 151 of FIG. 1 is now two separate lines: the transmit line 150 and receive line 154. Likewise the transmit/receive line 153 of FIG. 1 is shown in FIG. 2 as two separate lines: the transmit line 152 and receive line 156. The Ethernet port 414 and the Ethernet port 424 are communicatively coupled by a transmit line 452 and a receive line 456. Transmit lines 150, 152 and 452 transmit data packets from the first network processor 415 to the second network processor 425 as indicated by the direction of the arrow. Likewise, the receive lines 154, 156 and 456 transmit data packets to the first network processor 415 from the second network processor 425 as indicated by the direction of the arrow.

In one implementation of this embodiment, Ethernet port 112 is the active-receive Ethernet port and the Ethernet ports 114 and 414 are the backup-receive Ethernet ports. In this implementation, the Ethernet port 122 sends data packets to the active-receive Ethernet port 112 via the receive line 154, which is the primary receive line for the firs network processor 415. In this same implementation, there are three possible scenarios for the second network processor 425. In the first scenario, the Ethernet port 122 is the protected or active-receive Ethernet port and the Ethernet ports 124 and 424 are the backup-receive Ethernet ports. In the second scenario, the Ethernet port 124 is the protected or active-receive Ethernet port and the Ethernet ports 122 and 424 are the backup-receive Ethernet ports. In the third scenario, the Ethernet port 424 is the protected or active-receive Ethernet port and the Ethernet ports 122 and 124 are the backup-receive Ethernet ports. The communication links are configured as described above.

In one implementation of this embodiment, priority order is a user configurable option. For example in a first implementation of this embodiment, the Ethernet port 122 is the active-receive Ethernet port for the Ethernet-protection-switch system 11, the Ethernet port 124 is the first backup active-receive Ethernet port for the Ethernet-protection-switch system 11, and the Ethernet port 424 is the second backup active-receive Ethernet port for the Ethernet-protection-switch system 11. For example in a second implementation of this embodiment, the Ethernet port 122 is the active-receive Ethernet port for the Ethernet-protection-switch system 11, the Ethernet port 424 is the first backup active-receive Ethernet port for the Ethernet-protection-switch system 11, and the Ethernet port 124 is the second backup active-receive Ethernet port for the Ethernet-protection-switch system 11.

The second network processor 425 is configured to send duplicate data packets to the first network processor 415 via all the receive lines 154, 156 and 456. Only one of the three Ethernet ports 112, 114, or 414 in the first network processor 415 receives and duplicated data packet while the other two of the Ethernet ports 112, 114, or 414 discards the received data packets.

The first network processor 415 is configured to send duplicate data packets to the second network processor 425 via all the transmit lines 150, 152 and 452. Only one of the three Ethernet ports 122, 124, or 424 in the second network processor 425 receives and duplicated data packet while the other two of the Ethernet ports 122, 124, or 424 discards the received data packets.

The duplication of the data occurs at layer 2 of the OSI model so that at least a portion of the protection switching occurs at layer 2. In prior art protection switching techniques, data packet duplication occurs at the physical layer (layer 1) and the transmit signals on each line appear identical. By doing a portion of the protection switching at layer 2 as described herein, the physical layer signals are no longer necessarily identical. Since physical layer replication and matching is not required, the Ethernet-protection-switch system 11 has a physical layer independence. Thus, the ports and wires do not need to be identical. For example, in one implementation of this embodiment, the active port is electrical and the backup port is optical.

In one implementation of this embodiment, the receive capability of each backup Ethernet is disabled. In another implementation of this embodiment, the backup-receive Ethernet ports receive the data packets on the backup lines, and then discard the received data packet after the network processor acquires statistics for the received data packets. In this case, the statistics accumulated at the network processor are used to determine which communication link for the transceiver node is most efficient in receiving data packets.

The network processor 415 includes processing capability to determine which receive line is to be used to receive data packets at a given time. In one implementation of this embodiment, a non-revertive protection switching is implemented. In this case, a transceiver node continuously accepts data packets from the transmit/receive line communicatively coupled to the active-receive Ethernet port until there is a failure in the communication link that includes the active-receive Ethernet port and then the transceiver node begins to accept data packets from one of the transmit/receive lines communicatively coupled to one of the backup-receive Ethernet ports. In such an embodiment, the transceiver node continuously receive data packets from the new active-receive Ethernet port, until the new primary communication link fails.

In another implementation of this embodiment, revertive protection switching is implemented. In this case, when the failed communication link is recovered, the Ethernet-protection-switch system switches back to implementing the original communication link after it recovers and after a configurable timeout. The timeout prevents system instability in which the system is switched back and forth.

In the event that any portion of the primary communication link of a transceiver node goes down, one of the backup communication links becomes the primary communication link. The network processors 415 and 425 have processing capability to determine which backup communication link becomes the primary communication link when the current primary communication link fails. In one implementation of this embodiment, the determination about which backup communication link becomes primary communication link is based on statistics collected by the network processor regarding the quality of the data packets received at the network processors 415 and 425. In another implementation of this embodiment, the determination about which backup communication link becomes primary communication link is based on the quality of physical layer statistics or a simple round robin.

In one implementation of this embodiment of system 11, the transmit line 150, 152 and 452 and the respective receive lines 154, 156 and 456 are a single bidirectional transmit/receive line as shown in FIG. 1. In another implementation of this embodiment of system 11, the transmit lines 150, 152 and 452 and the respective receive lines 154, 156 and 456 are not located along the same path. In yet another implementation of this embodiment, none of the transmit lines 150, 152 and 452 or the receive lines 154, 156 and 456 are located along the same physical path. This decreases the likelihood of more than one of the transmit lines and/or receive lines being broken at the same time from a failure producing event. For example, a mechanical failure can be a break from a backhoe digging up the cables that include the transmit lines and/or receive lines. In another implementation of this embodiment, the transmit line 150 and the receive line 154 are installed together along a route that is physically separated from a route shared by the transmit line 152 and the receive line 156 and is also physically separated from a route shared by the transmit line 452 and the receive line 456. This decreases the likelihood that the paired transmit lines and receive lines mechanically fail at the same time as other paired transmit lines and receive lines.

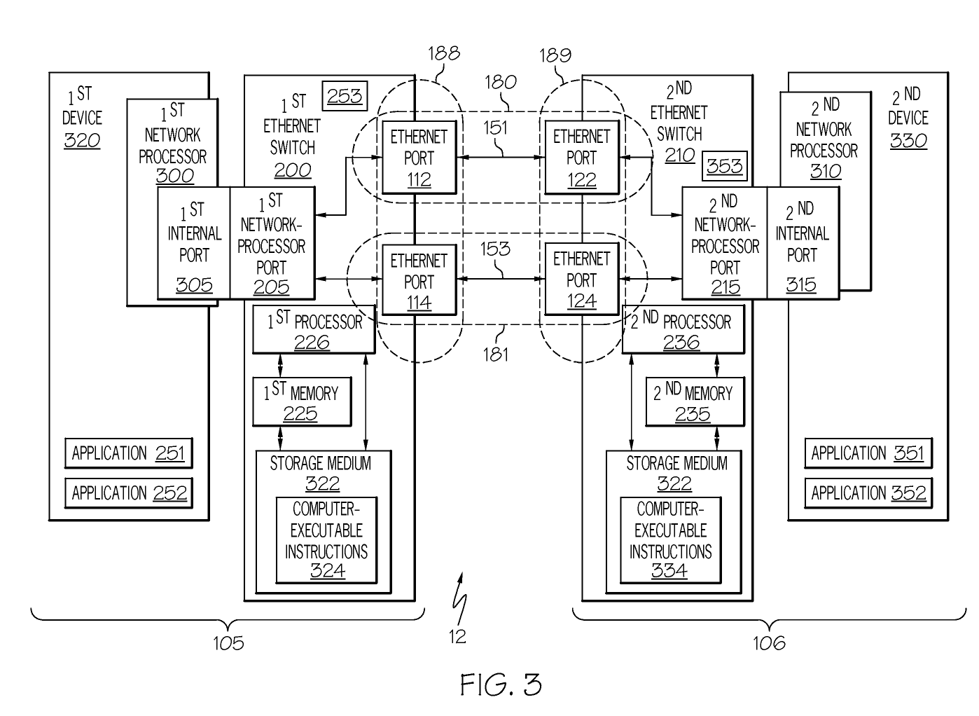

FIG. 3 is a block diagram representative of an Ethernet-protection-switch system 12. Ethernet-protection-switch system 12 includes a first transceiver node 105 and second transceiver node 106. The first transceiver node 105 includes a first Ethernet switch 200, and a first device 320. The first device 320 includes a first network processor 300, application 251, and application 252. The first network processor 300 has a first internal port 305.

The first Ethernet switch 200 includes a first network-processor port 205 that is communicatively coupled to the first internal port 305 of the first network processor 300. The first Ethernet switch 200 also includes two Ethernet ports 112 and 114. The Ethernet ports 112 and 114 are communicatively coupled to the first network-processor port 205 within the first Ethernet switch 200.

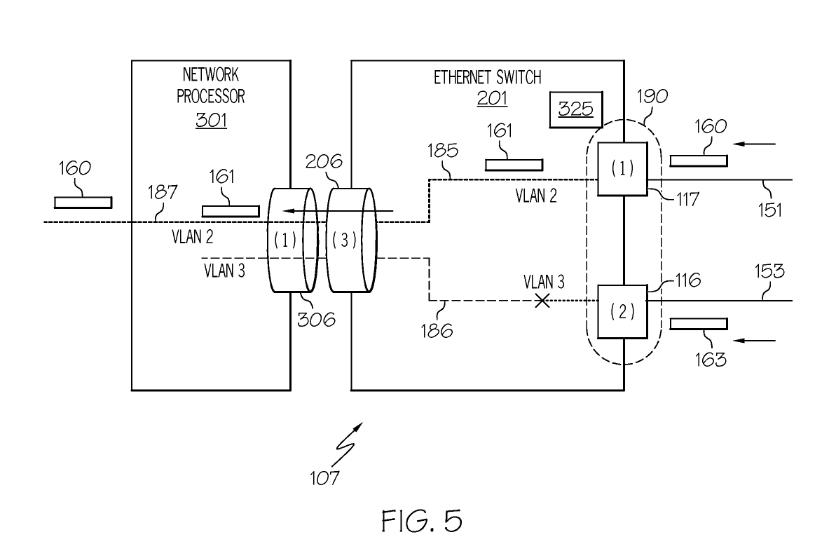

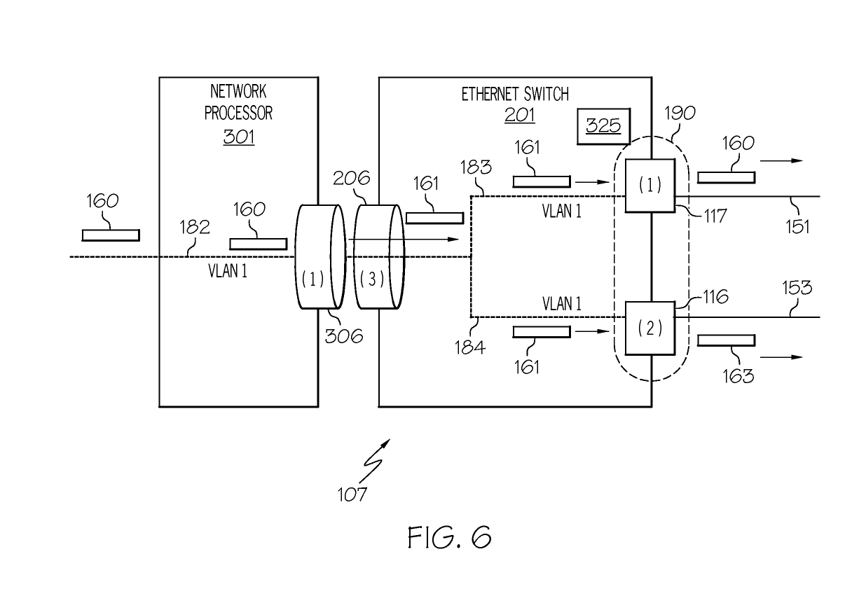

A first processor 226, a first memory 225 and a storage medium 322, which includes computer-executable instructions 324, are located within the first Ethernet switch 200. In one implementation of this embodiment, the first memory 225 stores an egress VLAN switching table, an ingress VLAN switching table, and a VLAN configuration table. The egress VLAN switching table, the ingress VLAN switching table, and the VLAN configuration table are described below with reference to FIG. 5 and FIG. 6, respectively. The first memory 225 is communicatively coupled to the first processor 226 and the storage medium 322. The first processor 226 is also communicatively coupled to the storage medium 322.

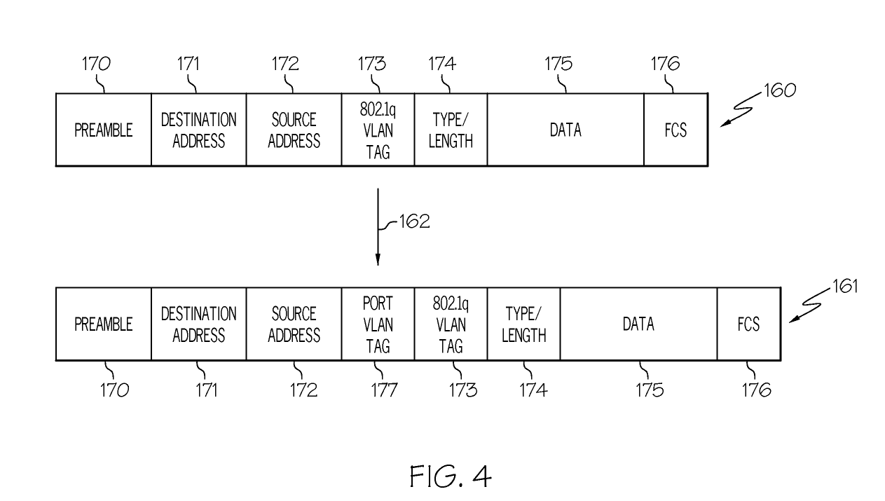

The first processor 226 directs data packets that are input to the first Ethernet switch 200 between the Ethernet ports 112 and 114 and the first network-processor port 205 based on the virtual local area network identifier in the data packet (and based on which of the Ethernet ports 112 or 114 is the active-receive Ethernet port), as is described in detail below with reference to FIGS. 4-7. The directing is also based on the ingress and egress VLAN switching tables stored in the first memory 225.

The second transceiver node 106 includes a second Ethernet switch 210 and a second device 330. The second device 330 includes a second network processor 310, application 351 and application 352. The second network processor 310 has a second internal port 315.

The second Ethernet switch 210 includes a second network-processor port 215 that is communicatively coupled to the second internal port 315 of the second network processor 310. The second Ethernet switch 210 also includes two Ethernet ports 122 and 124. The Ethernet port 122 and the Ethernet port 124 are communicatively coupled to the second network-processor port 215 within the second Ethernet switch 210.

A second processor 236, a second memory 235 and a storage medium 332 are located within the second Ethernet switch 210. The storage medium 332 includes computer-executable instructions 334. In one implementation of this embodiment, the second memory 235 stores an egress VLAN switching table, an ingress VLAN switching table, and a VLAN configuration table. The second memory 235 is communicatively coupled to the second processor 236 and the storage medium 332. The second processor 236 is also communicatively coupled to the storage medium 332

The second processor 236 directs data packets that are input to the Ethernet switch 210 between the third and fourth Ethernet ports 122 and 124, respectively, and the second network-processor port 215 based on the virtual local area network identifier in the data packet (and based on which of the Ethernet ports 122 or 124 is the active-receive Ethernet port), as is described in detail below with reference to FIGS. 4-7. The directing is also based on the ingress and egress VLAN switching tables stored in the second memory 235.

The transmit/receive lines 151 and 153 transmit data packets between the Ethernet switches 200 and 210 as described above with reference to FIG. 1. In one implementation of this embodiment, the transmit/receive line 151 is replaced by transmit line 150 and receive line 154 as described above with reference to FIG. 2. In another implementation of this embodiment, the transmit/receive line 153 is replaced by transmit line 152 and receive line 156 as described above with reference to FIG. 2.

Data packets received at the first Ethernet switch 200 from the first internal port 305 in the first network processor 300 are sent over the transmit/receive lines 151 and 153 from the first Ethernet switch 200 to the second Ethernet switch 210. The data packets sent to the second Ethernet switch 210 from the second internal port 315 in the second network processor 310 are sent over the transmit/receive lines 151 and 153 from the second Ethernet switch 210 to the first Ethernet switch 200.

In one implementation of this embodiment, the data packets sent over transmit/receive lines 151 and 153 from the first Ethernet switch 200 to the second Ethernet switch 210 are sent based on an egress VLAN switching table stored in the first memory 225 in the first Ethernet switch 200. In this case, the data packets sent from the second Ethernet switch 210 to the first Ethernet switch 200 over transmit/receive lines 151 and 153 are sent based on an egress VLAN switching table stored in the second memory 235 in the second Ethernet switch 210.

The Ethernet-protection-switch system 12 includes the status applications 253 and 353 to monitor the status of the communication link. The status applications 253 and 353 in the first Ethernet switch 200 and the second Ethernet switch 210, respectively, monitor the status of the communication link. For example, the first Ethernet switch 200 is configured to receive a failure status for the communication link, that includes the active-receive Ethernet port (Ethernet port 112 or Ethernet port 114), the communicatively coupled transmit/receive line (transmit/receive line 151 or 153, respectively), and the Ethernet port (Ethernet port 122 or 124, respectively) in the second Ethernet switch 210. If and when the communication link fails, the Ethernet switch accepts data packets from the transmit/receive line communicatively coupled to one of the backup-receive Ethernet ports and discards data packets from the transmit/receive line communicatively coupled to the previously active-receive Ethernet port responsive to receiving the failure status. In one implementation of this embodiment, the applications 251 and 351 in the first device 320 and the second device 330 are status applications 251 and 351 to monitor the status of the communication link.

In one implementation of this embodiment, the Ethernet port 112 is the active-receive Ethernet port and Ethernet port 114 is the backup-receive Ethernet port in the first Ethernet switch 200. In this case, the first Ethernet switch 200 is configured to accept data packets received on the transmit/receive line 151 and to discard data packets received on the transmit/receive line 153. In this case, either the Ethernet port 122 or the Ethernet port 124 can be the active-receive Ethernet port for the second Ethernet switch 210 as is understandable based on the above description.

In an exemplary case, the first Ethernet switch 200 is accepting data packets from the transmit/receive line 151 when the first network processor 300 receives a failure status for the communication link that includes the transmit/receive line 151. A failure status for the transmit/receive line 151 indicates that the transmit/receive line 151 in the communication link has failed or broken. Based on receiving the failure status for the communication link that includes the transmit/receive line 151, the first Ethernet switch 200 begins to accept data packets at the Ethernet port 114 from the transmit/receive line 153 and to send those accepted data packets to the first device 320. At the same time, the first Ethernet switch 200 begins to discard data packets at the Ethernet port 112 from on the transmit/receive line 151. The data packets are discarded at the first Ethernet switch 200.

In one implementation of this exemplary case, after the transmit/receive line 151 goes down, the Ethernet-protection-switch system 12 switches to transmit/receive line 153, and after the transmit/receive line 151 is restored to normal operation, the Ethernet-protection-switch system 12 is switched so that the first Ethernet switch 200 accepts data packets from the transmit/receive line 151 and discards data packets from transmit/receive line 153. In this case, first Ethernet switch 200 alters the node operation to accept and send data packets from the transmit/receive line 153 only if the transmit/receive line 151 is in failure mode.

In another implementation of this exemplary case, after the transmit/receive line 151 goes down, the Ethernet-protection-switch system 12 switches to transmit/receive line 153, and even after the transmit/receive line 151 is restored to normal operation, the Ethernet-protection-switch system 12 is not switched back. Thus, the first Ethernet switch 200 continues to accept data packets from the transmit/receive line 153 and to discard data packets from transmit/receive line 151. In this case, the first Ethernet switch 200 only alters the node operation to accept data packets from the transmit/receive line 153 and to discard data packets from transmit/receive line 153 if a failure status is received for the transmit/receive line 153.

The first network processor 300 views the Ethernet port 112 and Ethernet port 114 as a single logical port, so that logical port is protected by the Ethernet port 112 and Ethernet port 114. Likewise, the second network processor 310 views the Ethernet port 122 and Ethernet port 124 as a single logical port, so that logical port is protected by the Ethernet port 122 and Ethernet port 124.

Storage devices suitable for tangibly embodying computer program instructions and data include all forms of non-volatile memory, including by way of example: semiconductor memory devices, such as EPROM, EEPROM, and flash memory devices; magnetic disks such as internal hard disks and removable disks; magneto-optical disks; and DVD disks. Any of the foregoing may be supplemented by, or incorporated in, specially-designed application-specific integrated circuits (ASICs).

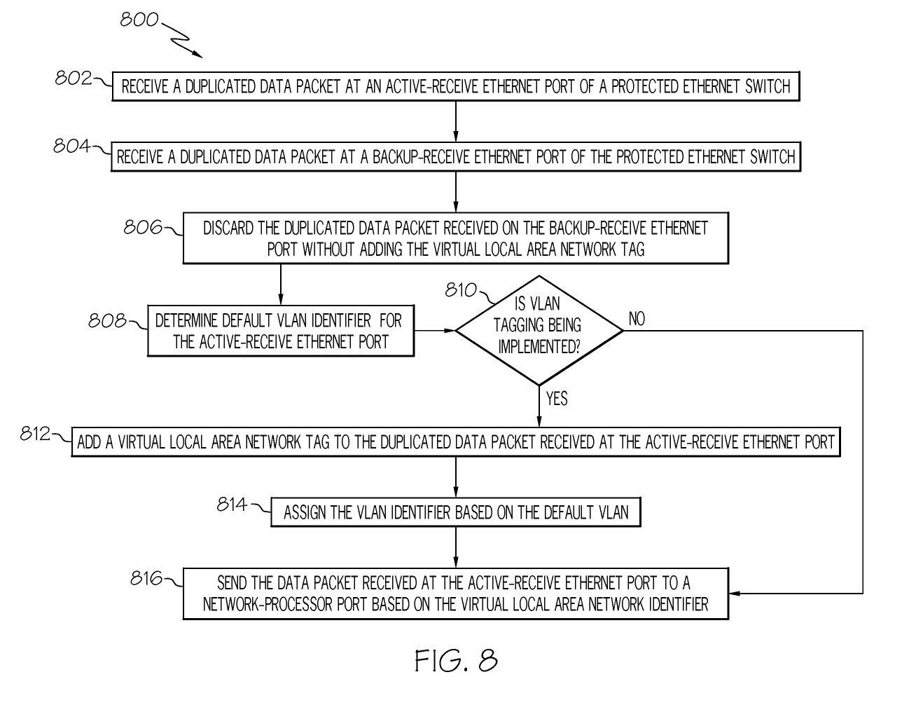

The first processor 226 executes computer-executable instructions 324, such as software, firmware or other program code that cause the first processor 226 to perform at least some of the processing described here as being performed during methods 800-1100 as described below with reference to FIGS. 8-11. At least a portion of such computer-executable instructions 324 and/or firmware executed by the first processor 226 and any related data structures are stored in storage medium 322 during execution. First memory 225 comprises any suitable memory now known or later developed such as, for example, random access memory (RAM), read only memory (ROM), and/or registers within the first processor 226. In one implementation, the first processor 226 comprises a microprocessor or microcontroller. Moreover, although the first processor 226 and first memory 225 are shown as separate elements in FIG. 3, in one implementation, the first processor 226 and first memory 225 are implemented in a single device (for example, a single integrated-circuit device). The first processor 226 executes computer-executable instructions 324, such as software, firmware or other program code for performing the methods 800-1200 as described below with reference to FIGS. 8-12. The computer-executable instructions 324 comprise a plurality of program instructions that are stored or otherwise embodied on a storage medium 322. In one implementation, the first processor 226 comprises processor support chips and/or system support chips such as ASICs.

Likewise, the second processor 236 executes computer-executable instructions 334, such as software, firmware or other program code for performing the methods 800-1200 as described below with reference to FIGS. 8-12. The computer-executable instructions 334 comprise a plurality of program instructions that are stored or otherwise embodied on a storage medium 332. In one implementation, the second processor 236 comprises processor support chips and/or system support chips such as ASICs.

Second memory 235 comprises any suitable memory now known or later developed such as, for example, random access memory (RAM), read only memory (ROM), and/or registers within the second processor 236. In one implementation, the second processor 236 comprises a microprocessor or microcontroller. Moreover, although the second processor 236 and second memory 235 are shown as separate elements in FIG. 3, in one implementation, the second processor 236 and second memory 235 are implemented in a single device (for example, a single integrated-circuit device). The computer-executable instructions 334 and/or firmware executed by the second processor 236 comprises a plurality of program instructions that are stored or otherwise embodied on a storage medium 332 from which at least a portion of such program instructions are read for execution by the second processor 236. In one implementation, the second processor 236 comprises processor support chips and/or system support chips such as ASICs.

In another implementation of this embodiment, the systems 10, 11 or 12 are configured so that system user is able to manually switch the active and backup ports. For example, when a user changes a cable to one of an active-receive Ethernet port, e.g., Ethernet port 112, the user types in a command at the user interface (not shown) to make the Ethernet port 112 the active port. Alternatively, the manual command will cause the protection switching to be disabled. In this manner, when the cable to the Ethernet port 112 is removed, the Ethernet port 114 continues to receive data packets. The user enables protection switching again after the cable is changed.

When the systems 10, 11, and 12 operate with VLAN identifiers, the data packets are virtual local area network (VLAN) data packets and VLAN tags are added to input data packets and removed from output data packets at the transceiver nodes 101-102, 103-104, and 105-106, respectively. FIG. 4 is a block diagram of an embodiment of a VLAN data packet 161 modified for ingress in the Ethernet switch 201 (FIG. 5). In this case, the VLAN data packet 160, which is modified to form data packet 161, is also referred to herein as “input data packet 160,” “duplicate data packet 160,” or “duplicated data packet 160.” FIG. 5 is a diagram of an embodiment of internal paths 185 and 187 for a modified data packet 161 received as a duplicated data packet 160 at Ethernet port 117 of a transceiver node 107.

The transceiver node 107 has the same physical structure as transceiver node 105 (FIG. 3). The transceiver node 107 includes a network processor 301 and an Ethernet switch 201. The network processor 301 is communicatively coupled to the active-receive Ethernet port 117 and the backup-receive Ethernet port 116 via the network-processor port 206 of the Ethernet switch 201 and the internal port 306 of the network processor 301. The network processor 301 views multiple external ports, such as Ethernet ports 117 and 116, as a single logical port 190. Thus, the logical port 190 of the network processor 301 is protected by Ethernet port 117 and Ethernet port 116.

The identical data packets 160 and 163 (FIG. 5) are transmitted according to the standards set by the Institute of Electrical and Electronics Engineers (IEEE) committee to develop Standards for Local and Metropolitan Area Networks Virtual Bridged Local Area Networks in the 802.1Q VLAN specification. Thus, the format of data packets 160 and 163 conform to the standards set by the Institute of Electrical and Electronics Engineers (IEEE) committee to develop Standards for Local and Metropolitan Area Networks Virtual Bridged Local Area Networks in the 802.1Q VLAN specification.

The duplicated data packet 160 and duplicated data packet 163 (shown as data packet 160 in FIG. 4) include the preamble field 170, the destination address field 171, the source address field 172, the 802.1Q VLAN tag 173, the type field/length 174, the data field 175, and the frame check sequence (FCS) field 176 as shown in FIG. 4. The 802.1Q VLAN tag 173 includes the tag protocol identifier followed by two octets of tag control information. The two octets of tag control information consist of three fields. The first field includes three bits, which indicate the user priority. The second field includes a one bit canonical format identifier (CFI). The remaining twelve bits are a network-based virtual local area network identifier that is required for the data packet 160 to be transmitted through the communication network.

In this exemplary embodiment of FIG. 5, the data packet 160 is transmitted on the transmit/receive line 151 and the duplicate data packet 163 is transmitted on the transmit/receive line 153. The data packet 160 is configured as modified data packet 161 that is sent to the network processor 301. When the modified data packet 161 is received at the network processor port 206 of the Ethernet switch 201, the modified data packet 161 is re-formed in the format of the data packet 160 for delivery to the network processor 301 via internal port 306. The duplicate data packet 163 received at the backup-receive Ethernet port 116 is discarded without modification since the receiver path identifier is disconnected at the physical layer. This is indicated by the X positioned on the internal path 186 between the Ethernet port 116 and the network processor port 206.

In the event that the transmit/receive line 151 goes down, the transceiver node 107 is protection switched so that the Ethernet port 116 becomes the active-receive Ethernet port and the duplicate data packet 163 is received at the Ethernet switch 201. During the protection switching process, the Ethernet port 116 is connected at the physical layer so that the data packet 163 is modified and sent to the network processor 301. At the same time, the Ethernet port 117 is disconnected at the physical layer so that the data packet 160 is discarded when it reaches the Ethernet port 117.

The primary data packet 160 is modified to form data packet 161 by the inclusion of a VLAN tag 177, between the source address field 172 and the 802.1Q VLAN tag 173 (FIG. 4). The term “VLAN tag” is also referred to here as “port VLAN tag.” The port VLAN tag 177 contains information indicative of the virtual local area network identifier (VLAN ID) and is configured according to the IEEE 802.1Q standards. Specifically, the port VLAN tag 177 includes the tag protocol identifier followed by two octets of tag control information. The port VLAN tag 177 is configured in the same manner as the 802.1Q VLAN tag 173 and includes two octets of tag control information that consist of three fields as described above.

In FIG. 5, each port of the transceiver node 107 is shown with a port number indicated in parenthesis. Specifically, the internal port 306 in the network processor 301 has a port identifier (ID) number “1.” The network-processor port 206 in the Ethernet switch 201 has an identifier number “3.” The active-receive Ethernet port 117 and backup-receive Ethernet port 116 in the Ethernet switch 201 have identifier numbers “1” and “2,” respectively. An ingress VLAN switching table is stored in a memory 325 in Ethernet switch 201. The memory 325 is similar in function and structure to first memory 225 as described above with reference to FIG. 3. The ingress VLAN switching table being implemented in FIG. 5 is shown in Table 6. The ingress VLAN switching table shows the correlation between a VLAN identifier (N) and communicatively coupled ports in the Ethernet switch 201. MAC address learning disabled

TABLE 6
Ingress VLAN Switching Table

| VLAN Identifier (ID) | Port ID | Port ID |
|---|---|---|
| 2 | 1 | 3 |
| 3 | 2 | 3 |

As indicated by the exemplary ingress VLAN switching table shown in Table 6, the duplicated data packet 160 received at port 1 (Ethernet port 117) is formed into modified data packet 161 with a port VLAN tag 177 (FIG. 4) that includes a VLAN identifier 2. The Ethernet switch 201 sends the modified data packet 161 from port 1 (Ethernet port 117) via internal path 185 to port 3 (network-processor port 206).

Likewise, the exemplary ingress VLAN switching table shown in Table 6 indicates that a duplicated data packet 163 received at port 2 (Ethernet port 116), when the transmit/receive line 153 is the active transmit/receive line, is formed into data packet 161 with a port VLAN tag 177 (FIG. 4) that includes a VLAN identifier 3. The data packet 161 is sent to port 3 (network-processor port 206).

In one implementation of this embodiment, the exemplary data packet 160 is being transmitted in a communication network (not shown) that includes the first device 320 and the first Ethernet switch 200 in transceiver node 105 as shown in FIG. 3. In another implementation of this embodiment, the exemplary data packet 160 is being transmitted in a communication network (not shown) that includes the network processor 415 as shown in FIG. 2. In yet another implementation of this embodiment, in order to reduce processing time, when VLAN tag 177 is added, the frame check sequence at the end of the Ethernet packet is not recalculated. The data packet is still the same when VLAN tag 177 is removed and the frame check sequence is still valid.

In yet another embodiment, the transceiver node is the transceiver node 105 of FIG. 3 and the first device 320 includes a provider bridge (not shown). In this case, the data packet received at the first device 320 includes a provider bridge VLAN tag that is configured according to the IEEE 802.1AD standards. Details about the insertion and removal of provider bridge VLAN tags are described in the '782 application.

In yet another implementation of this embodiment, the duplicate data packet 163 is processed at the packet layer (layer 2) and all the received duplicate data packets 163 are checked for port quality and integrity at port 2 (Ethernet port 116) prior to be being discarded. For example, statistics can be collected regarding cyclic redundancy check errors, length errors, and/or aborted data packets at both the Ethernet port 117 and 116. The accumulated statistics are used to determine the relative performance of the Ethernet ports 117 and 116 and their respective communicatively coupled transmit/receive lines 151 and 153. IN this case, the Ethernet port line with the better performance is selected to be the active-receive Ethernet port. When statistics are collected on the duplicated data packet 163, the VLAN tag and VLAN ID are not added to the data packet 163 before it is discarded.

In yet another implementation of this embodiment, a configuration table is stored in the Ethernet switch 210 along with the ingress and egress switching tables. The configuration table is implemented when the Ethernet switch 201 is initiated to configure the ports that form a protection-port pair 190 for a logical port. For Ethernet switch 201, the configuration table implemented during initiation is shown in Table 7. Table 7 indicates that Ethernet port 117 and 116 are the protection-port pair 190 for the single logical port of the transceiver node 107.

TABLE 7

| Logical Port | Ethernet port | Ethernet port |
|---|---|---|
| network-processor port 206 (3) | Ethernet port 117 (1) | Ethernet |
| | | port 116 (2) |

A VLAN configuration table specifies the default VLAN ID for a given port. In one implementation of this embodiment, the ports have more than one VLAN ID associated with them and the default VLAN is used unless a user specifies the alternate VLAN ID. When a data packet arrives at an Ethernet port, the configuration table that specifies the default VLAN is used to determine which VLAN to assign to the data packet. An exemplary VLAN configuration table is shown in Table 8.

TABLE 8

Port Number

| | 1 | 2 | 3 |
|---|---|---|---|
| Default VLAN | VLAN 2 | VLAN 3 | VLAN 1 |

The switching described herein can be implemented without VLAN tags when there is no port multiplexing. For switches that do not need explicit tags, the data packets are not tagged, but rest of the described processes are the same. In an exemplary case in which the switch does not use VLAN tag, the data packet arrives at port 1 (Ethernet port 117), the default VLAN ID is VLAN 2, the data packet is switched according to VLAN 2 based on the switching table entry, but a VLAN tag is not added to the packet.

The backup-receive Ethernet port 116 is still active to transmit data packets out of the Ethernet switch 201 even though the receiver path identifier is disconnected at the physical layer of the backup-receive Ethernet port 116. This is shown in FIG. 6. FIG. 6 is a diagram of an embodiment of internal paths 182, 183, and 184 for modified data packets 161 sent as unmodified data packets 160 from Ethernet ports 117 and 116 of a transceiver node 107. The transceiver node 107 of FIG. 6 is the same transceiver node 107 of FIG. 5 but the internal paths 182, 183, and 184 taken by the data packets 161 during egress differ from the internal paths 185, 186, and 187 taken by the primary data packets 161 during ingress. The egress and ingress directions have independent VLAN switching tables. The VLAN identifiers (ID) correlated to each port of the Ethernet switch 201 are the same as in FIG. 5.

The exemplary data packets 160 and 161 shown in FIG. 6 are the data packets described above with reference to FIG. 4. In order to switch output data packet 160 during egress from a transceiver node 107 via both the active-receive Ethernet port 117 and the backup-receive Ethernet port 116, the data packet 160 is configured with an additional VLAN tag within the network processor 301. As shown in FIG. 6, the VLAN identifier 1 in the VLAN tag 177 is added to the data packet 160 to form the modified data packet 161, when data packet 160 is received at the network processor 301 from an application. If there is more than one port in the network processor 301 connected to more than one Ethernet switch 201, a switching table is included in the network processor 301 as is understandable based on reading this specification. The data packet 161 is delivered to the Ethernet switch 201 via internal port 306 and network-processor port 206.

In one implementation of this embodiment, the VLAN ID is added by the internal port 306 in the network processor 301. In another implementation of this embodiment, the VLAN ID is added by the network-processor port 206 of the Ethernet switch 201. In yet another implementation of this embodiment, there is no VLAN ID added to the data packet 160 and the data packet 160 is sent via paths 183 and 184 to the respective Ethernet ports 117 and 116.

The Ethernet switch 201 switches the data packet 161 to the Ethernet ports 117 and 116 based on the VLAN identifier 1. An egress VLAN switching table is stored in the memory 325 within the Ethernet switch 201. The egress VLAN switching table being implemented in FIG. 6 is shown in TABLE 9.

MAC address learning disabled

TABLE 9
Egress VLAN Switching Table

| VLAN Identifier | | | |
|---|---|---|---|
| (ID) | Port ID | Port ID | Port ID |
| 1 | 1 | 2 | 3 |

As indicated by the exemplary egress VLAN switching table shown in Table 8, a data packet 160 received at port 3 (network-processor port 206) receives the VLAN identifier 1 and is sent to both ports in the protection-port pair 190, i.e., port 1 (Ethernet port 117) and port 2 (Ethernet port 116).

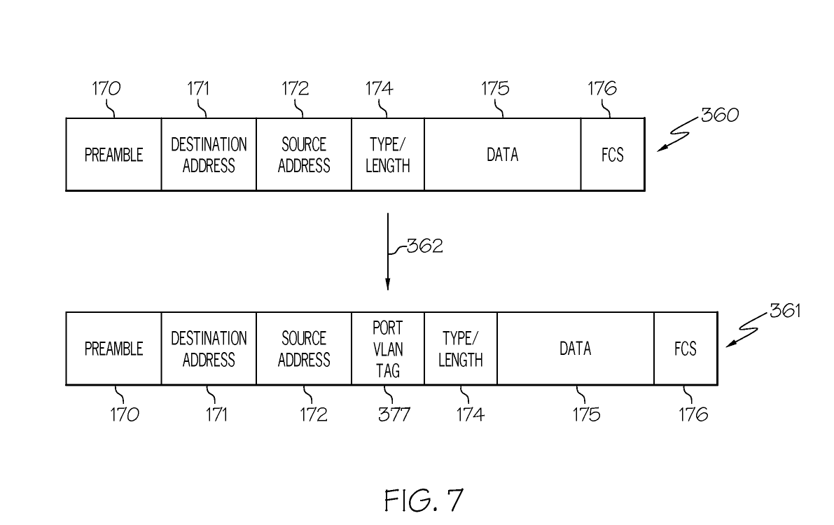

In one implementation of this embodiment, the data packet received at the transceiver node 107 does not include an 802.1Q VLAN tag 173. FIG. 7 is a block diagram of an embodiment of a VLAN data packet 361 modified for ingress to Ethernet switch 201 (FIG. 5). In this case, the VLAN data packet 360 is referred to as “input data packet 360” or “duplicated data packet 360.” Data packet 360 is similar to data packet 160 except there is no 802.1Q VLAN tag 173. Specifically, data packet 360 is configured according to the IEEE 802.3-2002 standards for Ethernet frames without virtual local area network tags. The data packet 360 is configured in a manner that enables the addition of a VLAN tag for switching in the transceiver node 105 so that data packet 361 is formed. The data packet 361 is an Ethernet frame, which is modified to include an additional a port VLAN tag 377.

The above description of FIGS. 5 and 6 with reference to the data packets 160 and 161 is also applicable to data packets 360 and 361, respectively. The sole difference is that when switching data packet 361 between the network processor 301 and the Ethernet ports 117 and 116 of the Ethernet switch 201, the data packet 361 is configured with port VLAN tag 377, between the source address field 172 and the type field/length 174.

The port VLAN tag 377 is equivalent to port VLAN tag 177 of FIG. 4. Thus, the port VLAN tag 377 contains information indicative of the virtual local area network identifier (VLAN ID) and is configured according to the IEEE 802.1Q standards. Specifically, the port VLAN tag 377 includes the tag protocol identifier followed by two octets of tag control information. The port VLAN tag 377 includes two octets of tag control information that consist of three fields as described above with reference to FIG. 4.

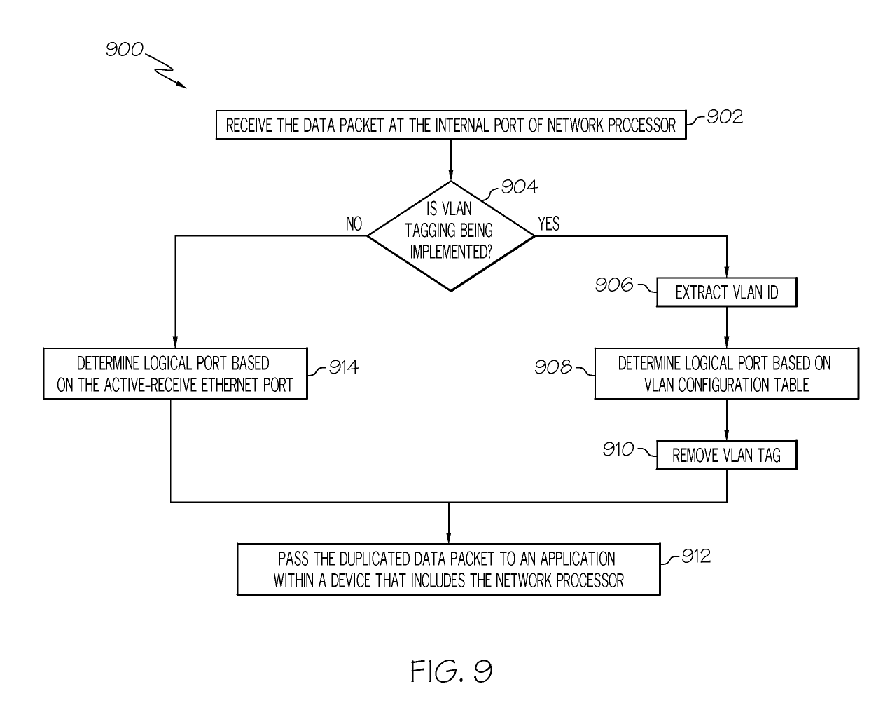

The methods of adding and removing the VLAN tags are summarized below with reference to the methods 800-1200 of FIGS. 9-12, respectively. Methods 800-1200 are described with reference to Ethernet-protection-switch system 12 of FIG. 3 and with reference to FIGS. 4-6. The discussion of methods 800-122 is made with reference to only the one transceiver node 105 (FIG. 3), therefore the “first Ethernet switch 200” is referred to as the “Ethernet switch 200,” the “first network-processor port 205” is referred to as the “network-processor port 205,” the “first memory 225” is referred to as the “memory 225,” the “first internal port 305” is referred to as the “internal port 305,” the “first network processor 300” is referred to as the “network processor 300,” and the “first device 320” is referred to as the “device 320.”

FIG. 8 is a flow diagram of one embodiment of a method 800 to protection switch input data packets for ingress in accordance with the present invention. Method 800 describes the process for ingress of the input data packets 160 from the active-receive Ethernet port 112 and the backup-receive Ethernet port 114 to the network-processor port 205 (FIG. 3). At block 802, a duplicated data packet 160 is received at an active-receive Ethernet port 112 of a protected Ethernet switch 200 via transmit/receive line 151. The terms Ethernet switch and protected Ethernet switch are used interchangeably herein. At block 804, a duplicated data packet 160 is received at a backup-receive Ethernet port 114 of the protected Ethernet switch 200 via transmit/receive line 153. At block 806, the duplicated data packet 160 received at the backup-receive Ethernet port 114 is discarded at the Ethernet switch 200 without adding the virtual local area network tag and identifier to the duplicated data packet 160. Thus, the virtual local area network identifier (VLAN ID) is not inserted into the data structure of the virtual local area network tag 177 of the duplicate data packet that is received at the backup-receive Ethernet port 114.

At block 808, the default the value for the virtual local area network identifier (VLAN ID) is determined for the active-receive Ethernet port. The value of the VLAN ID is based on the active-receive Ethernet port that received the data packet.

At block 810, it is determined if VLAN tagging is being implemented in the system. If VLAN tagging is being implemented, the flow of method 800 proceeds to block 812. At block 812, the data structure for the four bytes of a virtual local area network tag 177 is added to the duplicated data packet 160 received at the active-receive Ethernet port 112. At block 814, the VLAN identifier is assigned based on the default VLAN determined at block 808. Thus, the value for VLAN ID is inserted into the data structure of the virtual local area network tag 177 to form a modified data packet 161 (FIG. 4). The flow of method 800 proceeds to block 816 from block 814.

If it was determined at block 810, that the VLAN tagging is not being implemented in the system, the flow of method 800 proceeds to block 816. At block 816, the data packet 160 or the modified data packet is sent to the network-processor port 205 in the Ethernet switch 200 based on the virtual local area network identifier VLAN ID determined at block 808. The data packet sent to the network-processor port 205 is data packet 160 if the VLAN tagging is not being implemented and blocks 812 and 814 are not implemented. The data sent to the network-processor port 205 is data packet 161 if the VLAN tagging is being implemented and blocks 812 and 814 were implemented.

FIG. 9 is a flow diagram of one embodiment of a method 900 to protection switch input data packets for ingress in accordance with the present invention. Method 900 describes the process for ingress of the data packet 160 or modified data packet 161 from the network-processor port 205 to the application 252 in the device 320 (FIG. 3). The VLAN de-tagging processes of method 900 can occur at either the network-processor port 205 or the internal port 305 of the network processor 300. The flow is described below for the VLAN de-tagging processes of method 900 occurring at the network-processor port 205. However, one skilled in the art who reads the description of method 900 will understand how the VLAN de-tagging processes of method 900 can be implemented at the internal port 305.

At block 902, the modified data packet 161 or data packet 160 is received at the network-processor port 205 in the Ethernet switch 200. At block 904, it is determined if VLAN tagging is being implemented by the system. If the data packet received at the network-processor port 205 is the data packet 160, VLAN tagging is not being implemented. If the data packet received at the network-processor port 205 is the modified data packet 161, VLAN tagging is being implemented. If it is determined that VLAN tagging is being implemented by the system, the flow of method 900 proceeds to block 906.

At block 906, the virtual local area network identifier is extracted from the port VLAN tag 177 in modified data packet 161. In one implementation of this embodiment, the processor 226 in the Ethernet switch 200 extracts the virtual local area network identifier from the port VLAN tag 177 in modified data packet 161. At block 908, the logical port is determined based on the active-receive Ethernet port and the VLAN configuration table, such as Table 7 shown above. At block 910, the virtual local area network tag 177 is removed from the modified data packet 161 to re-form the duplicated data packet 160. In one implementation of this embodiment, the processor 226 in the Ethernet switch 200 removes the port VLAN tag 177 from the modified data packet 161 to re-form the duplicated data packet 160. Blocks 906-910 are the steps required for the de-tagging process.

The flow proceeds to block 912 and the re-formed duplicated data packet 160 is transmitted to the network processor 300 via the network processor port 305. At block 912, the duplicated data packet 160 is passed to an application 251 or 252 within the device 320 that includes the network processor 300. The re-formed duplicated data packet 160 is passed via the internal port 305 in the network processor 300 of the device 320.

If it is determined that VLAN tagging (and de-tagging) is not being implemented by the system, the flow of method 900 proceeds to block 914. At block 914, the logical port is determined based on the active-receive Ethernet port for the data packet 160 and the configuration table, such as Table 7 shown above. The flow proceeds from block 914 to block 912. At block 912, the duplicated data packet 160 is passed to an application 251 or 252 within the device 320 that includes the network processor 300. The formed duplicated data packet 160 is passed via the internal port 305 in the network processor 300 of the device 320.

If the processes of method 900 occur at the internal port 305 of the network processor 300, the data packet 160 or the modified data packet 161 is passed from the network-processor port 205 to the internal port 305. If the modified data packet 161 is passed to the internal port 305, the VLAN tag is removed from the modified data packet 161 at the internal port 305.

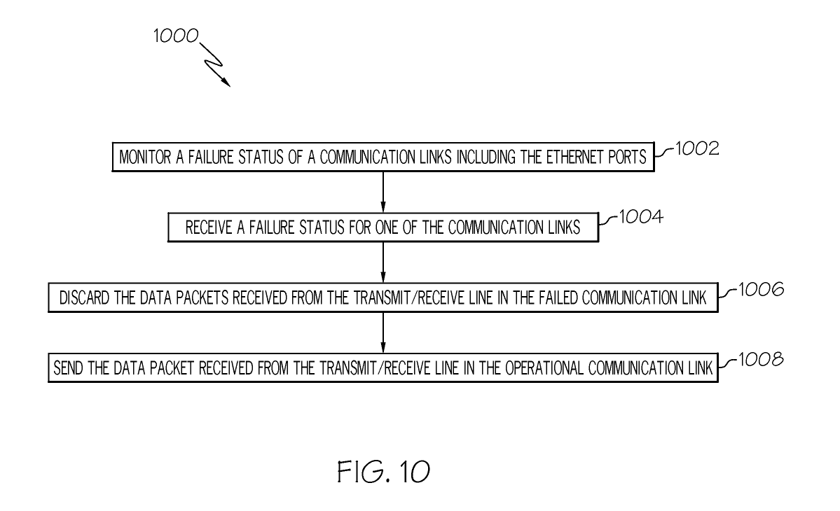

FIG. 10 is a flow diagram of one embodiment of a method 1000 to protection switch input data packets 160 for ingress in accordance with the present invention. At block 1002, a failure status of communication links including the Ethernet ports is monitored. In one implementation of this embodiment, the processor 226 in the Ethernet switch 200 monitors the communication link including the active-receive Ethernet port 112, the transmit/receive line 151, and the Ethernet port 122 for a failure status. In another implementation of this embodiment, the processor 226 in the Ethernet switch 200 monitors for a failure status of both the communication link that includes the active-receive Ethernet port 112, the transmit/receive line 151, and the Ethernet port 122 and the communication link that includes the backup-receive Ethernet port 114, the transmit/receive line 153, and the Ethernet port 124.

At block 1004, a failure status for one of the communication links is received. In one implementation of this embodiment, the processor 226 receives the failure status for the active communication link that includes the active-receive Ethernet port 112, the transmit/receive line 151, and the Ethernet port 122.

At block 1006, the input data packets 160 received from the failed communication link are discarded based on the receipt of the failure status. The processor 226 disables the active-receive Ethernet port if the duplicated data packets 160 communication link that includes the active-receive Ethernet port fails.

In one implementation of this embodiment, the processor 226 reconfigures the Ethernet switch 200 to discard the data packets 160 received from the transmit/receive line 151 if the duplicated data packets 160 were being accepted from the active transmit/receive line 151 when a failure status was received for communication link that includes the transmit/receive line 151. In another implementation of this embodiment, the processor 226 reconfigures the Ethernet switch 200 to discard the data packets 160 received from the transmit/receive line 153 if the duplicated data packets 160 were being received from the active transmit/receive line 153 when a failure status was received for communication link that included the transmit/receive line 153. In yet another implementation of this embodiment, the Ethernet switch 200 is not reconfigured if the duplicated data packets 160 were being received from the transmit/receive line 153 when a failure status was received for the communication link that includes the transmit/receive line 151. In yet another implementation of this embodiment, the Ethernet switch 200 is not reconfigured if the duplicated data packets 160 were being received from the transmit/receive line 151 when a failure status was received for the communication link that includes the transmit/receive line 153.

At block 1008, the data packet 160 received at the operational transmit/receive line is sent to the network processor 300. In one implementation of this embodiment, the duplicated data packet 160 received at the operational transmit/receive line is modified by the Ethernet switch 201 and the modified data packet 161 is sent to the network processor 301 (FIG. 5).

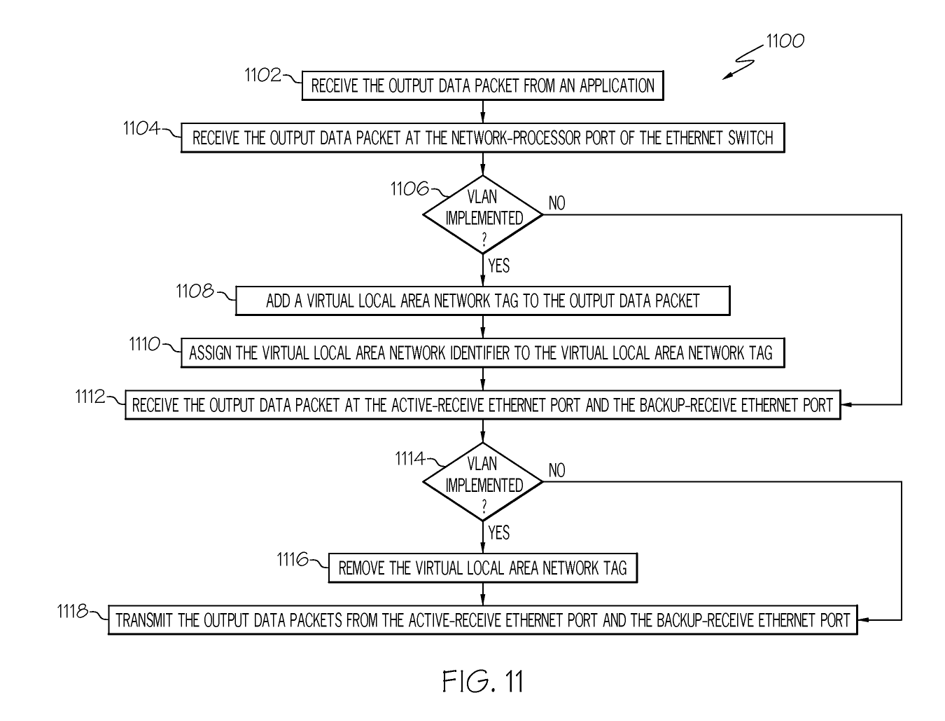

FIG. 11 is a flow diagram of one embodiment of a method 1100 to protection switch output data packets 160 for egress in accordance with the present invention. Method 1100 describes the process for egress of the data packet 160 from the application to the Ethernet ports 112 and 114 (FIG. 3). The VLAN tagging processes of method 1100 can occur at either the network-processor port 205 of Ethernet switch 200 or the internal port 305 of the network processor 300. The flow is described below for the VLAN tagging processes of method 1100 occurring at the network-processor port 205. However, one skilled in the art who reads the description of method 1100 will understand how the processes of method 1100 can be implemented at the internal port 305 of the network processor 300.

At block 1102, the output data packet 160 is received from an application 251 at the network processor 300 in device 320 (FIG. 3). At block 1104, the data packet 160 is received at the Ethernet switch 200. The output data packet 160 is received from the internal port 305 of the network processor 300 at the network processor port 205 of the Ethernet switch 200. At block 1106, it is determined if VLAN tagging is being implemented. If it is determined that VLAN tagging is being implemented by the system, the flow of method 1100 proceeds to block 1108. At block 1108, a virtual local area network tag 177 is added to the output data packet 160 to form the data packet 161. At block 1110, the virtual local area network identifier, such as VLAN 1, is assigned to the virtual local area network tag 177. At block 1112, the data packet 161 is received at the active-receive Ethernet port 112 and the backup-receive Ethernet port 114.

If it is determined that VLAN tagging is not being implemented by the system, the flow of method 1100 proceeds to block 1112 from block 1106 and the data packet 160 is received at the active-receive Ethernet port 112 and the backup-receive Ethernet port 114.

At block 1114, it is determined if VLAN tagging is being implemented. If it is determined that VLAN tagging is being implemented by the system, the flow of method 1100 proceeds to block 1116. At block 1116, the VLAN tag is removed from the data packet 161. Specifically, the virtual local area network identifier, such as VLAN ID 1, is extracted from the VLAN tag 177 in the data packets 161 received at the active-receive Ethernet port 112 and the backup-receive Ethernet port 114 and the virtual local area network tag 177 is removed from the data packets 161 received at the active-receive Ethernet port 112 and the backup-receive Ethernet port 114 to form the output data packet 160. The flow proceeds to block 1118.

If it is determined that VLAN tagging is not being implemented by the system, the flow of method 1100 proceeds to block 1118 from block 1114. At block 1118, the output data packet 160 is transmitted (as duplicated data packets) from both the active-receive Ethernet port 112 and the backup-receive Ethernet port 114.

The methods and techniques described here may be implemented in digital electronic circuitry, or with a programmable processor (for example, a special-purpose processor or a general-purpose processor such as a computer) firmware, software, or in combinations of them. Apparatus embodying these techniques may include appropriate input and output devices, a programmable processor, and a storage medium tangibly embodying program instructions for execution by the programmable processor. A process embodying these techniques may be performed by a programmable processor executing a program of instructions to perform desired functions by operating on input data and generating appropriate output. The techniques may advantageously be implemented in one or more programs that are executable on a programmable system including at least one programmable processor coupled to receive data and instructions from, and to transmit data and instructions to, a data storage system, at least one input device, and at least one output device. Generally, a processor will receive instructions and data from a read-only memory and/or a random access memory.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. An Ethernet-protection-switch system comprising:
a first transceiver node having Ethernet ports, the Ethernet ports including one active-receive Ethernet port and at least one backup-receive Ethernet port;
transmit/receive lines communicatively coupled to a respective one of the Ethernet ports, each transmit/receive line carrying duplicates of a data packet sent from a communicatively coupled second transceiver node,
wherein the duplicated data packet input from a transmit/receive line to the active-receive Ethernet port is received at the first transceiver node,
wherein the duplicated data packet input from a transmit/receive line to a respective one of the at least one backup-receive Ethernet port is discarded at the first transceiver node, and
wherein, if the transmit/receive line inputting the duplicated data packet to the active-receive Ethernet port fails, one of the at least one backup-receive Ethernet ports begins to function as the active-receive Ethernet port, wherein the first transceiver node is configured to output duplicated data packets from each of the Ethernet ports for transmission on each of the transmit/receive lines.

2. The Ethernet-protection-switch system of claim 1, the system comprising:
a second transceiver node having Ethernet ports, the Ethernet ports including one active-receive Ethernet port and at least one backup-receive Ethernet port,
wherein the transmit/receive lines are communicatively coupled to a respective one of the Ethernet ports of the second transceiver node,
wherein the Ethernet ports in the second transceiver node are communicatively coupled to a respective one of the Ethernet ports in the first transceiver node in a point to point configuration,
wherein, each transmit/receive line carries a duplicated data packet sent from the first transceiver node,
wherein the duplicated data packet input from a transmit/receive line to the active-receive Ethernet port in the second transceiver node is received at the second transceiver node,
wherein the duplicated data packet input from a transmit/receive line to a respective one of the at least one backup-receive Ethernet port in the second transceiver node is discarded at the second transceiver node, and
wherein, if the transmit/receive line inputting the duplicated data packet to the active-receive Ethernet port in the second transceiver node fails, one of the at least one backup-receive Ethernet ports in the second transceiver node begins to function as the active-receive Ethernet port, wherein the second transceiver node is configured to output duplicated data packets from each of the Ethernet ports in the second transceiver node for transmission on each of the transmit/receive lines to the first transceiver node.

3. The Ethernet-protection-switch system of claim 2, wherein each transceiver node comprises a network processor having the one active-receive Ethernet port and the at least one backup-receive Ethernet port, the network processor configured to accept the data packet input from the transmit/receive line communicatively coupled to the active-receive Ethernet port and to discard the duplicated data packet input from the others of the transmit/receive lines, the network processor further configured to output duplicated data packets from each of the Ethernet ports in the network processor for transmission on each of the transmit/receive lines.

4. The Ethernet-protection-switch system of claim 3, wherein each transmit/receive line communicatively coupling an Ethernet port in a first network processor to an Ethernet port in a second network processor comprises:
a transmit line to transmit data packets output from the Ethernet port in the first network processor to the communicatively coupled Ethernet port in the second network processor; and
a receive line to transmit data packets output from the Ethernet port in the second network processor to the communicatively coupled Ethernet port in the first network processor.

5. The Ethernet-protection-switch system of claim 2, wherein each transceiver node comprises:
a network processor having an internal port; and
an Ethernet switch including:
a network-processor port communicatively coupled to the internal port of the network processor;
the Ethernet ports communicatively coupled to the network-processor port; and
a memory located within the Ethernet switch, the memory storing a switching table.

6. The Ethernet-protection-switch system of claim 5, wherein the Ethernet switch in each transceiver node includes the active-receive Ethernet port and the at least one backup-receive Ethernet port,
wherein data packets received from a first internal port in a first network processor at a first Ethernet switch are output from the active-receive Ethernet port and each of the at least one backup-receive Ethernet ports in the first Ethernet switch to be sent over the transmit/receive lines to the second Ethernet switch; and
wherein data packets received from a second internal port in a second network processor at a second Ethernet switch are output from the active-receive Ethernet port and each of the at least one backup-receive Ethernet ports in the second Ethernet switch to be sent over the transmit/receive lines to the second Ethernet switch.

7. The Ethernet-protection-switch system of claim 6, further comprising:
an egress VLAN switching table stored in a first memory in the first Ethernet switch; and
an egress VLAN switching table stored in a second memory in the second Ethernet switch, wherein duplicated data packets sent over the transmit/receive lines from the first Ethernet switch to the second Ethernet switch are sent based on the egress VLAN switching table stored in the first memory and wherein duplicated data packets sent over the transmit/receive lines from the second Ethernet switch to the first Ethernet switch are sent based on the egress VLAN switching table stored in the second memory.

8. The Ethernet-protection-switch system of claim 7, wherein the network processor is configured to receive data packets from the Ethernet switch based on an ingress VLAN switching table, the system further comprising:
a status application to monitor a status of the communication link including the active-receive Ethernet port, wherein the Ethernet switch is configured to receive a failure status for the communication link including the active-receive Ethernet port when the communication link including the active-receive Ethernet port fails, wherein the Ethernet switch accepts data packets from the transmit/receive line communicatively coupled to one of the at least one backup-receive Ethernet ports and discards data packets from the transmit/receive line communicatively coupled to the active-receive Ethernet port responsive to receiving the failure status.

9. The Ethernet-protection-switch system of claim 6, further comprising:
a first device comprising the first network processor and at least one application; and
a second device comprising the second network processor and at least one application.

10. The Ethernet-protection-switch system of claim 6, further comprising:
a status application to monitor a status of the communication link including the active-receive Ethernet port, wherein the Ethernet switch is configured to receive a failure status for the communication link including the active-receive Ethernet port when the communication link including the active-receive Ethernet port fails, wherein the Ethernet switch accepts data packets from the transmit/receive line communicatively coupled to one of the at least one backup-receive Ethernet ports and discards data packets from the transmit/receive line communicatively coupled to the active-receive Ethernet port responsive to receiving the failure status.

11. A method to protection switch Ethernet ports, the method comprising:
receiving a duplicated data packet at an active-receive Ethernet port of a protected Ethernet switch;
receiving a duplicated data packet at a backup-receive Ethernet port of the protected Ethernet switch;
adding a virtual local area network tag to the duplicated data packet received at the active-receive Ethernet port;
assigning a virtual local area network identifier to the virtual local area network tag based on the Ethernet port that received the duplicated data packet to form a modified data packet;
discarding the duplicated data packet received on the backup-receive Ethernet port; and
sending the modified data packet to a network-processor port based on the virtual local area network identifier.

12. The method of claim 11, wherein protection switching input data packets for ingress further comprises:
receiving the modified data packet at the network-processor port of the Ethernet switch;
extracting the virtual local area network identifier;
removing the virtual local area network tag to re-form the duplicated data packet;
transmitting the re-formed duplicated data packet to a network processor via a network processor port;
receiving the re-formed duplicated data packet at the network processor via an internal port; and
passing the re-formed duplicated data packet to an application within a device that includes the network processor.

13. The method of claim 12, further comprising:
monitoring a failure status of communication links including the Ethernet ports.

14. The method of claim 13, further comprising:
receiving a failure status for one of the communication links;
discarding the data packets received from the transmit/receive line in the failed communication link based on the receipt of the failure status; and
sending the data packet received from the transmit/receive line in the operational communication link.

15. The method of claim 12, further comprising:
receiving an output data packet from an application in a device at an internal port of a network processor in the device;
adding a virtual local area network tag to the output data packet; and
assigning the virtual local area network identifier to the virtual local area network tag based on the internal port.

16. The method of claim 15, further comprising:
receiving the output data packet at a network processor port of the Ethernet switch;
receiving the output data packet at an active-receive Ethernet port and the backup-receive Ethernet port;
extracting the virtual local area network identifier;
removing the virtual local area network tag; and
transmitting the output data packet from the active-receive Ethernet port and the backup-receive Ethernet port.

17. A method to protection switch Ethernet ports, the method comprising:
receiving a duplicated data packet at an active-receive Ethernet port of a protected Ethernet switch;
receiving a duplicated data packet at a backup-receive Ethernet port of the protected Ethernet switch;
discarding the duplicated data packet received at the backup-receive Ethernet port; and
sending the duplicated data packet received at the active-receive Ethernet port to a network-processor port.

18. The method of claim 17, further comprising:
receive the duplicated data packet at a network processor; and
pass the duplicated data packet to an application within a device that includes the network processor.

19. The method of claim 17, further comprising:
receiving the output data packet from an application in a device that includes a network processor;
receiving the output data packet at the Ethernet switch;
receiving the output data packet at the active-receive Ethernet port and the backup-receive Ethernet port; and
transmitting the output data packet from the active-receive Ethernet port and the backup-receive Ethernet port.

20. A program product comprising program instructions, embodied on a storage medium, that are operable to cause a processor to:
add a virtual local area network tag to a duplicated data packet received at an active-receive Ethernet port;
assign a virtual local area network identifier to the virtual local area network tag based on the active-receive Ethernet port that received the active data packet to form a modified data packet;
discard the duplicated data packet received on a backup-receive Ethernet port; and
send the modified data packet to a network-processor port of the Ethernet switch based on the virtual local area network identifier.

21. The program product of claim 20, wherein program product comprising program instructions, embodied on a storage medium, that are further operable to cause a processor to:
extract the virtual local area network identifier from the modified data packet received at the network-processor port of the Ethernet switch;
remove the virtual local area network tag to re-form the duplicated data packet;
and transmit the re-formed duplicated data packet to a network processor via a network processor port.

22. The program product of claim 20, wherein program product comprising program instructions, embodied on a storage medium, that are further operable to cause a processor to:
add a virtual local area network tag to an output data packet received from an application in a device at an internal port of a network processor in the device; and
assign the virtual local area network identifier to the virtual local area network tag based on the internal port.

23. The program product of claim 22, wherein program product comprising program instructions, embodied on a storage medium, that are further operable to cause a processor to:
extract the virtual local area network identifier from the output data packet received at the active-receive Ethernet port and the backup-receive Ethernet port from the network-processor port;
remove the virtual local area network tag; and
transmit the output data packets from the active-receive Ethernet port and the backup-receive Ethernet port.

24. A program product comprising program instructions, embodied on a storage medium, that are operable to cause a processor to:
discard a duplicated data packet received at a backup-receive Ethernet port of a protected Ethernet switch; and
send a duplicated data packet received at an active-receive Ethernet port of the protected Ethernet switch to a network-processor port.
